(19) United States
(12) Patent Application Publication
(10) Pub. No.: US 2016/0099569 A1
(43) Pub. Date: Apr. 7, 2016

(54) ENERGY GENERATING DEVICE WITH FUNCTIONALLY RELIABLE POTENTIAL SEPARATION

(71) Applicant: REFUSOL GMBH, Metzingen (DE)

(72) Inventors: Sebastian RILLING, Reutlingen (DE); Konstantin PONJAKIN, Tuebingen (DE)

(21) Appl. No.: 14/889,167

(22) PCT Filed: May 5, 2014
(86) PCT No.: PCT/EP2014/059045

§ 371 Date: Nov. 5, 2015

(30) Foreign Application Priority Data
May 6, 2013 (DE) 10 2013 104 629.0

(51) Int. Cl. H02J 3/38; G01R 31/333

(52) U.S. Cl. CPC H02J 3/38; G01R 31/333

(57) ABSTRACT

An energy generating device for generating electric energy from an energy source, in particular a regenerative energy source, and for feeding the generated electric energy into a grid, in particular a power supply grid, comprises: a power converter for converting energy at its input into a grid compatible energy at its output, at least one electric line for electrically connecting the output of the power converter to the grid, a separation device for a potential separation of the power converter from the grid, a noise filter device for discharging high-frequency interference signals against a reference point, a measuring device for capturing discharge currents flowing over the noise filter element and for delivering a discharge current signal characterizing a respective discharge current, and a control device for controlling the switch elements of the separation device.

The present invention relates to an energy generating device for generating electric energy from an energy source, in particular a regenerative energy source, and for feeding the generated electric energy into a grid, in particular a power supply grid, with a separation device for potential separation of a power inverter of the energy generating device from the grid, as well as a method for checking the functional reliability of a potential separation device of this kind.

Energy generating plants, e.g. photovoltaic (PV) plants, wind power plants, fuel cell based plants, etc., are usually connected, for example, to a power supply grid via a separation device allowing, if required, a potential separation of the energy generating device from the grid. It is, for example, obligatory that, in case of a grid breakdown or of a disconnection of a grid for maintenance purposes or in case of dangerous fault currents or leakage currents at the inverter or capacitor, inverters of energy generating plants autonomously and automatically disconnect, effecting a separation from the grid. By means of the separation device all grounded and ungrounded live conductors of the energy generating plant are to be separated from the grid.

Secure and reliable functioning of a potential separation device of an energy separating plant is crucial. Usually the separation device comprises controllable electromagnetic switches, e.g. contactors or relays, which are able to effect a galvanic separation. Due to high currents in operation, environment impact, corrosion and further factors, the switch contacts of such relays or contactors may agglutinate or get jammed and then remain closed even when they are controlled for opening. Such a defect has to be identified and quickly eliminated as this would otherwise be dangerous, e.g. for individuals responsible for maintenance of the grid. Because of this, for the sake of safety, in a separation device in each connection line usually two switch elements are arranged in series, which can be controlled for opening separately from each other, to achieve a redundancy for a case of emergency.

The norm DIN EN 62109-2 demands that in the future inverters of an energy generating plant will have to independently check the insulation of the autonomous separation device before starting operation. Each individual fault or defect, in particular a jamming or agglutinating of a contact of one of the switches of the separation device, has to be securely identified and, in case of a fault, a connection to the grid has to be prevented.

Thus there is a demand for a functional reliability check, for the purpose of checking the potential separation e.g. of an inverter from a power supply grid, which check allows securely identifying a defect of a switch element of the potential separation device.

For this purpose safety relays or safety contactors might be used, which have an integrated self-checking and diagnostics function and can provide self-diagnostic results regarding their functional reliability via feedback outputs. However, safety relays or safety contactors of this type are complex and expensive and, moreover, not usually present in already existing energy generating plants. A functional reliability check of the potential separation device would be desirable for existing energy generating plants as well.

Furthermore solutions are known from the practical field, which provide additional measuring apparatuses at the output of the inverter, for example for measuring potentials at various points of the connection lines, e.g. directly at the switch elements of the separation device, and thus identifying a switch defect. These measuring devices also increase a complexity and a realization effort for the power converters and cannot or practically not be retrofitted in already existing energy generating plants.

Starting from this, it is an objective of the present invention to find a procedure allowing a functional reliability check of a separation device of an energy generating plant with a relatively low effort, which can also be implemented into already existing energy generating plants at low effort. In particular, it is an objective of the present invention to create an energy generating plant with a power converter and a separation device for potential separation of the power converter from a grid, as well as a method for checking the functional reliability of the potential separation device, both of which allow a function check in particular of the controllable switch elements of the potential separation device in a fashion that is as simple as possible. For this purpose, components usually applied in energy generating plants should be used if possible, to allow retrofitting of existing plants with little installation effort.

This objective is achieved according to the invention by the energy generating device with the features of patent claim 1 and by the method for checking the functional reliability of a potential separation device of an energy separating device according to claim 15.

The energy generating device for generating electric energy from an energy source, in particular a regenerative energy source, and for feeding the generated electric energy into a grid, in particular a power supply grid, comprises a power converter, at least one electric line, a separation device, a noise filter device, a measuring device and a control device. The power converter is designed for converting energy at its input into a grid compatible energy at its output, and may be, for example, a frequency converter or an inverter, depending on the type of plant. The at least one electric line is provided to electrically connect the output of the power converter to the grid. The separation device is provided for the potential separation of the power converter from the grid in case of a fault or demand and comprises a series circuit that is arranged in the at least one electric line and consists of at least two separately controllable switch elements. The noise filter device is provided for noise suppression measures, and thus for electromagnetic compatibility, and comprises at least one noise filter element, which is connected to the at least one electric line between the output of the power converter and the separation device, to discharge high-frequency interference signals against a reference point, e.g. apparatus ground or protective ground or functional ground. The measuring device is provided to capture discharge currents flowing over the noise filter element and to deliver a discharge current signal characterizing a respective discharge current. The control device is provided to control the switch elements of the separation device in order to operatively control said switch elements, in operation for closing and in case of a fault or demand for opening. According to the invention, the control device is furthermore designed for the function check of the separation device, in order to optionally control at least one of the switch elements of the at least one series circuit for closing, to receive a discharge current signal from the measuring device as a reaction to the closing of the switch and to identify by the discharge current signal a defect of at least one other of the switch elements of the at least one series circuit of the separation device.

According to the invention, a defect of one of the switch elements of the separation device is detected by the at least one further switch element of the separation device being closed and by capturing the reaction of an equalizing current generated by the at least one noise filter element of the noise filter device, which equalizing current allows deducting that there is a switch defect. A “defect” is to be understood, in this context, in particular as the misfunction that the respective switch element remains closed although being controlled for opening, e.g. due to a contact of a switch for galvanic separation being jammed or agglutinated.

In this regard it is crucial that the at least one noise filter element of the noise suppression filter device is arranged, if viewed from the grid, after or downstream (in normal operation of the energy generating device before or upstream) of the separation device such that, in case of a fault, a discharge current respectively equalizing current can flow off from the grid to the reference point, in particular the apparatus ground or functional ground, via the separation device and the noise filter element. This is generally provided in energy generating plants, e.g. with inverters, which advantageously allows usage of already existing components of a plant. The function check according to the invention can be implemented at comparably little effort and requires only few or none additional structural elements for this. In any case, complexity is low, thus also reducing installation effort. In the simplest case, the solution for the function check may be implemented in a purely software technological fashion, which allows retrofitting already existing plants without further ado, e.g. via tele-maintenance. In any case, the method according to the invention allows an efficient and reliable monitoring of the functionality of the potential separation device of an energy generating device.

The energy generating device according to the invention is preferably a photovoltaic device for generating electric energy from energy supplied by a photovoltaic generator via a preferably transformerless photovoltaic inverter. In such inverters a functionally reliable insulation or separation of the inverter from the grid is necessarily required, e.g. for grid maintenance, to protect people working on the grid from electric shocks, in particular if no additional separating transformer is provided. The energy generating plant may, however, also be used for wind power plants, for energy generating plants based on fuel cells, etc. The energy generating plant may also be used to feed a consumer if the consumer is able to re-feed electric energy into the energy generating plant. This may, for example, be the case with an electric drive system comprising a motor-generator, which is fed in motor operation by the energy generating device and which can in generator operation re-supply current to the energy generating device. In this regard, a “grid” is herein also to mean a customer of this type, who is able to receive current from and supply current to the energy generating device.

In one embodiment of the invention, in particular for photovoltaic applications, the power converter is implemented by a one-phase or multi-phase inverter, in particular a photovoltaic inverter, which converts input-side DC voltage energy into output-side AC voltage energy and the output of which comprises at least one first phase terminal and a neutral terminal. The at least one electric line then comprises at least one first phase conductor connected to the first phase terminal and a neutral conductor connected to the neutral terminal. In addition an apparatus ground or a functional ground is provided. The separation device comprises a first series circuit of at least one first and one second switch element, which are arranged in the first phase conductor. The separation device can also comprise a further series circuit of at least one first and one second switch element, which are arranged in the neutral conductor. Thus all grounded and non-grounded current-conducting conductors can be separated from the grid in accordance with the norm.

In the meaning used herein, the “at least one electric line” comprises one line, two lines or three and more lines. Depending on a case at hand, the at least one electric line may contain only lines with potential separation or as an alternative lines with and lines without potential separation. In the case of an AC voltage grid, the at least one electric line is, for example, one neutral conductor and at least one phase conductor.

The energy generating device can also be provided for a multi-phase AC voltage grid and comprise, for example, a three-phase inverter with three phase terminals, one neutral terminal and a grounding at its output, three phase conductors, one neutral conductor and one ground connection, each respectively running between one of the phase terminals or the neutral terminal or the grounding of the inverter output and an allocated grid-side terminal. In this case, in each phase conductor as well as in the neutral conductor respectively one series circuit consisting of at least one first and one second switch element of the separation device may be provided. Of course, a two-phase implementation is also possible.

For augmented reliability, the separation device may comprise more than two separately controllable switch elements in each series circuit of the at least one electric line. Thereby better insulation is achievable due to larger total air breaks of all switch elements of a series circuit. Furthermore, in case one of the switch elements does not work and the air break at the other switch elements is already reduced due to corrosion, contamination or the like, a sufficient total air break can be ensured. For the functional reliability check of the separation device, the control device is in this case preferably designed to optionally control simultaneously all but a single one of the switch elements of each series circuit for closing, to receive as a reaction a discharge current signal respectively an equalizing current signal from the measuring device, and to identify a defect of the one single switch element of the respective series circuit by the current signal.

Preferably electromagnetic switches, in particular contactors or relays, are applied as controllable switch elements for the separation device. These are easily controllable and are suitable for the power provided, for example, in photovoltaic plants or the like. As an alternative or additionally, semiconductor switch elements, e.g. bipolar power transistors, MOSFET power transistors, IGBTs or the like may be used, depending on the application at hand. In normal operation all switch elements of all series circuits of the separation device are closed by the control device. If a potential separation of the power converter from the grid is to be effected, all switch elements are controlled for opening.

In one advantageous embodiment each contactor or relay comprises two or several switch contacts of the same type, which are arranged in different conductors of the at least one electric line, e.g. in different phase conductors, or in a neutral connector and one or several phase conductors, and are controllable together via one single control circuit. Thus the effort for controlling and for the functional reliability check of the switch elements can be reduced.

The noise filter device may comprise different filter components for reducing common-mode or differential-mode interference signals, which are in particular caused by the power converter. These components can be arranged between the power converter-side output and the grid-side output in all conductors of the at least one electric line. These may preferably be, in particular, grid filters which are embodied as low pass or bandpass filters and are preferentially inserted between the separation device and the grid-side terminal. The at least one noise filter element, which in the function check, in case of a fault of the separation device, initiates the discharge current due to equalizing processes, is however arranged between the power converter-side output and the separation device.

In one implementation the at least one noise filter element is simply a noise capacitor, which is connected between a phase conductor of the at least one electric line and a ground, apparatus ground (protective ground, PE) or functional ground (FE). For each phase conductor at least one noise capacitor of this type is provided. Such noise capacitors are usually already present in power converters of energy generating plants, in particular in PV inverters. In such cases already existing structural components may be used for the function check of the separation device.

In one particularly preferred implementation, the measuring device is part of an all-current sensitive fault current monitoring unit. Such all-current sensitive fault current monitoring units are integrated in modern transformerless inverters to capture all kinds of fault currents respectively leakage currents against the ground, e.g. direct currents, alternating currents and pulsed currents. The all-current sensitive fault current monitoring unit may then also capture, in the functional reliability check of the separation device, a possibly occurring equalizing current and deliver a correspondent current signal to the control device.

In an especially advantageous implementation, the measuring device comprises a measuring current converter implemented as a differential current sensor, through which are looped all conductors of the at least one electric line running between the current-side terminals and the grid-side terminals, i.e. all phase conductors and the neutral conductor, and which is provided to capture the difference or sum of all currents flowing in the conductors. The differential current sensor may in particular be part of the all-current sensitive fault current monitoring unit, thus allowing to make use of structural components of already existing energy generating plants, which are present anyway.

The control device and the measuring device are preferably provided to carry out the functional reliability check of the separation device before the power converter, in particular inverter, starts operation. For example, the power converter, in particular a PV inverter, may be completely supplied by the DC voltage of a generator, in particular a PV generator. As soon as, for example in the early hours of a morning, a sufficiently large DC voltage is present at the PV inverter, the PV inverter provides a DC voltage that is above the peak grid voltage. The PV inverter first carries out a feed-forward control routine for synchronizing with the grid and connects to the grid as soon as it is synchronous with the grid. The function check according to the invention is carried out previous to the feed-forward control routine to prevent, in case of a defect, the inverter starting operation.

For evaluating the discharge current signal received from the measuring device in the function check of the separation device, the control device may comprise a comparator device, which compares the received discharge current signal to a given threshold value and states a defect of the separation device if the threshold value is exceeded. A threshold value can be suitably set on the basis of the parameters of the grid, of the noise filter device, of the impedance of the at least one electric line, etc.

In an advantageous implementation the control device is provided to simultaneously control at least two first respectively two second switch elements in different phase conductors or in a phase conductor and a neutral conductor for opening or closing. This is useful in particular in combination with contactors or relays which comprise at least two switch contacts that are controllable together. The effort for realization and the space required for the structural components can be reduced. The actuation is simplified. The check of the functional reliability of the separation device is also facilitated and accelerated as simultaneously defects in different single conductors and simultaneous faults in two conductors can be detected. In the latter case of a two-fold fault, the captured equalizing current respectively the differential current respectively added-up current, which has been captured by the differential current sensor, is even more evident, thus allowing an even more precise, secure and quick capturing.

In addition to the redundancy created by two switch elements per conductor, the control device may also be implemented in a redundant fashion, to the purpose of further enhancing the functional reliability. In particular, the control device may comprise two separate control units, e.g. processors, micro-processors, micro-controllers or the like. A first control unit may, for example, serve for controlling the first switch elements of all series circuits, while a second control unit may be provided for controlling the second switch elements of all series circuits. Thus the functional reliability check is also carried out by different control units respectively processor units, as a result of which respective faults in these units are also considered as regards achieving the required fault tolerance of the autonomous separation device. In each single-fault case scenario including an actuation or a switch element, at least one control unit and one switch element remain in the neutral conductor and in a phase conductor, ensuring a technically correct separation of the power converter from the grid.

The function check according to the invention is generally limited to the switch elements of the separation device that are contained in the phase conductors. As the neutral conductor is usually connected grid-side to the protective ground conductor (PE conductor), there is no voltage difference between the neutral conductor and the PE conductor in the ideal case. Thus, if one of the switch elements of the separation device in the neutral conductor jams and the other one is closed, no equalizing process takes place. To the purpose of allowing a reliable functional reliability check of the switch elements in the neutral conductor as well, the control device according to the invention preferably additionally takes an insulation measurement of the power converter into account.

In particular, the energy generating device according to the invention preferably further comprises an insulation measuring device for determining an insulation resistance of the power converter. An insulation measuring device of such a type is usually present, for detecting insulation faults, in power converters, in particular inverters, of energy generating plants, and is in this case additionally used, according to the invention, for the function check of the separation device. For this purpose, the control device controls one of the switch elements in the neutral conductor for closing and identifies a defect of another one of the switch elements in the neutral conductor by the insulation resistance determined by the insulation measuring device. In case of a faulty jamming or agglutination of the switch contact of the other switch element, the power converter is connected to the grid galvanically, depending on grid type, and an insulation is hence no longer provided. An extremely low insulation resistance thus indicates such a defect of the other switch element.

According to a further aspect of the invention, furthermore a method has been created for checking the functional reliability of a potential separation device of an energy generating device for generating electric energy from an energy source, in particular a regenerative energy source, and for feeding the generated electric energy into a grid, in particular a power supply grid. The energy generating device comprises a power converter for converting energy at its input into a grid compatible energy at its output, at least one electric line for electrically connecting the output of the power converter to the grid, the separation device for potential separation of the power converter from the grid, the separation device including a series circuit that is arranged in the at least one electric line and consists of at least two separately actuable switch elements, which are preferably provided for galvanic separation, and comprises a noise filter device which includes at least one noise filter element that is connected to the at least one electric line between the output of the power converter and the separation device, for discharging high-frequency interference signals against a reference point, in particular against a ground or against a neutral conductor. According to the invention, in the functional reliability check method, which is preferably carried out before the power converter, in particular an inverter, starts operation and is connected to the grid, first one of the switch elements of the at least one series circuit is controlled for closing, following which an equalizing current caused by the at least one noise filter element as a reaction thereto is measured and a defect, a jamming or agglutination of a contact of at least one other or the switch elements of the at least one series circuit is identified by the measured equalizing current.

The method steps described above are repeated for all switch elements of the separation device. This allows securely detecting single defects in any of the switch elements of the separation device, in particular in any of the phase conductors. The method is simple and can be carried out quickly. Besides this, the aspects, advantages, exemplary embodiments and application possibilities of the method according to the invention correspond to those described above in the context of the energy generating device according to the invention.

Preferably, for carrying out the method according to the invention an energy generating device is used as has been described in detail above.

Further advantageous details of preferred implementations of the invention are the subject-matter of the drawings, the description or the subclaims. In the drawings non-restricting exemplary embodiments of the invention are depicted.

It is shown in:

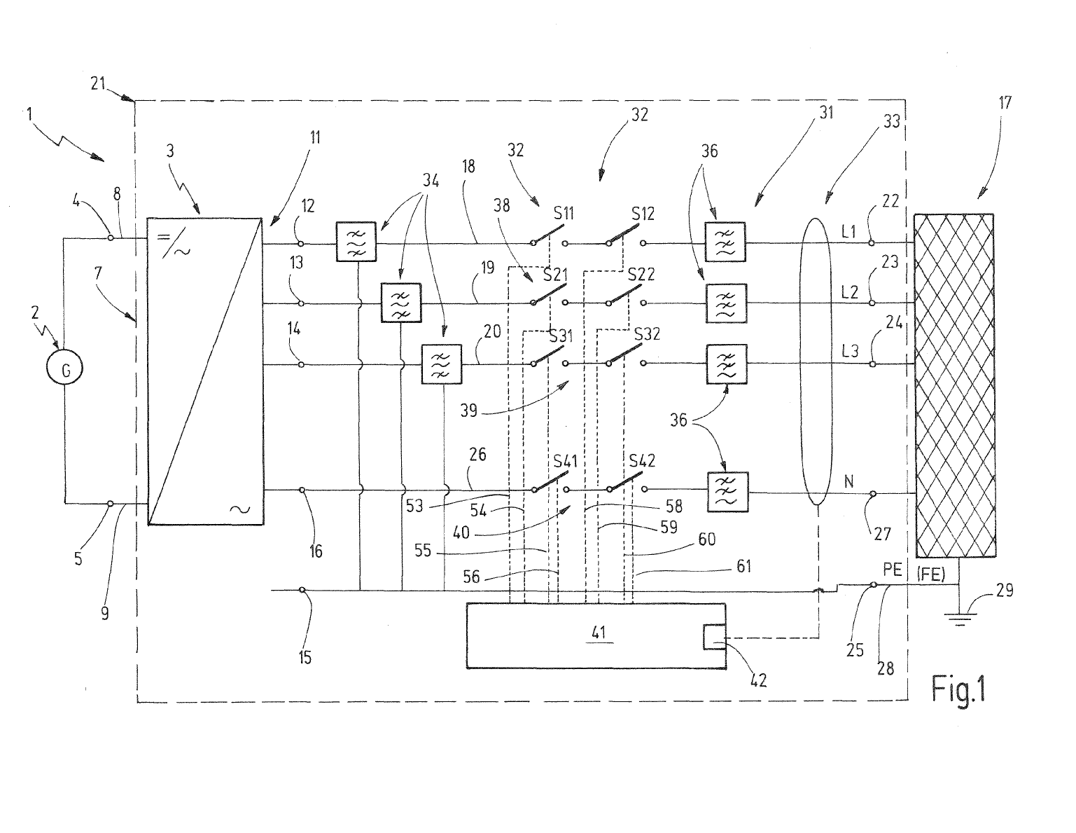

FIG. 1 a schematic presentation of an energy generating plant for generating and feeding electric energy in a grid, with a device for a function check of a separation device for potential separation of the plant from the grid according to aspects of the invention, in a largely simplified presentation;

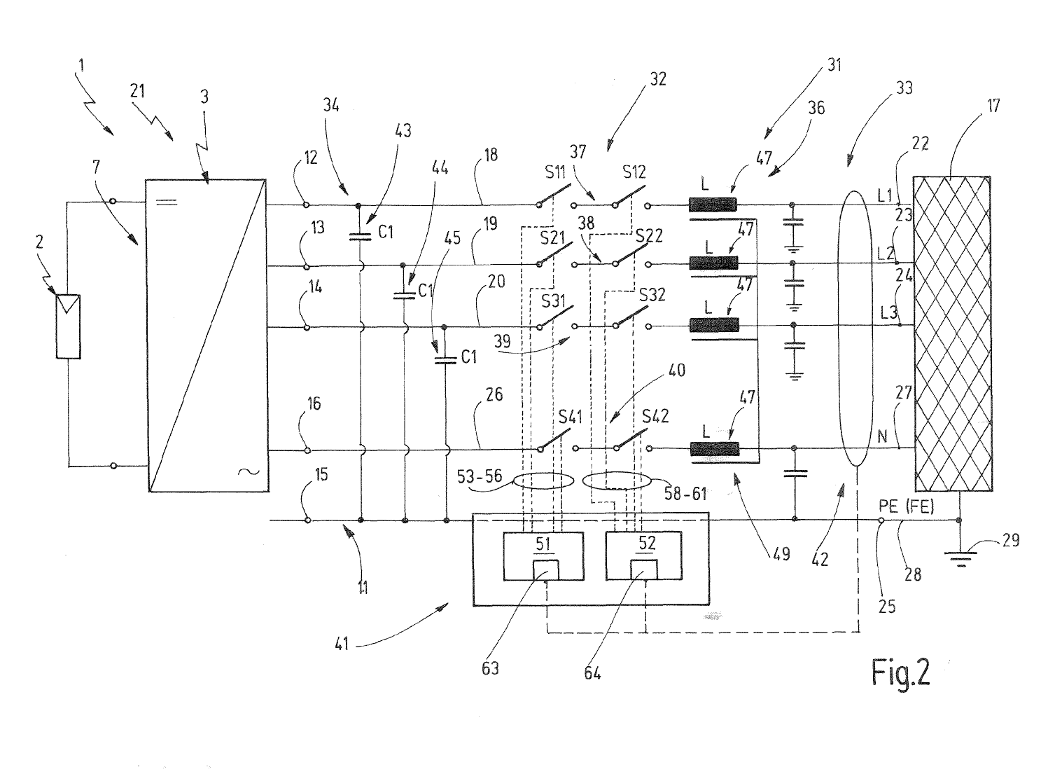

FIG. 2 a preferred embodiment of the energy generating plant according to FIG. 1, in a simplified presentation comprising more details than FIG. 1;

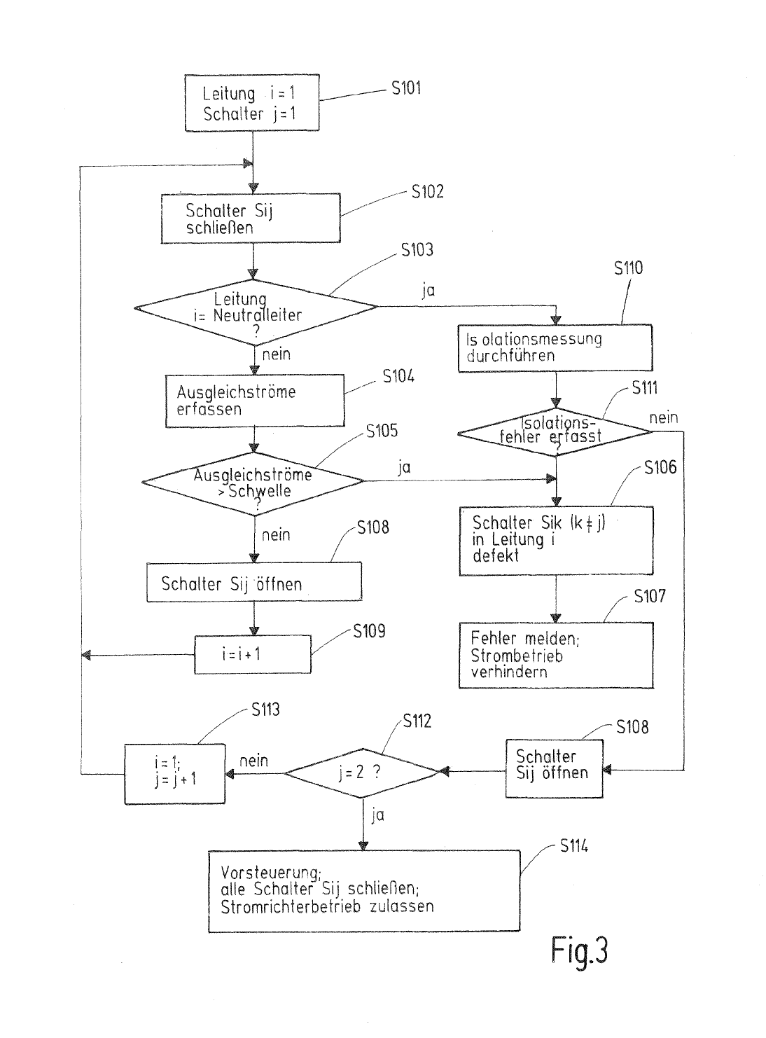

FIG. 3 a flow chart for a function check of the separation device of the energy generating plant according to FIG. 1 or 2, in a simplified presentation;

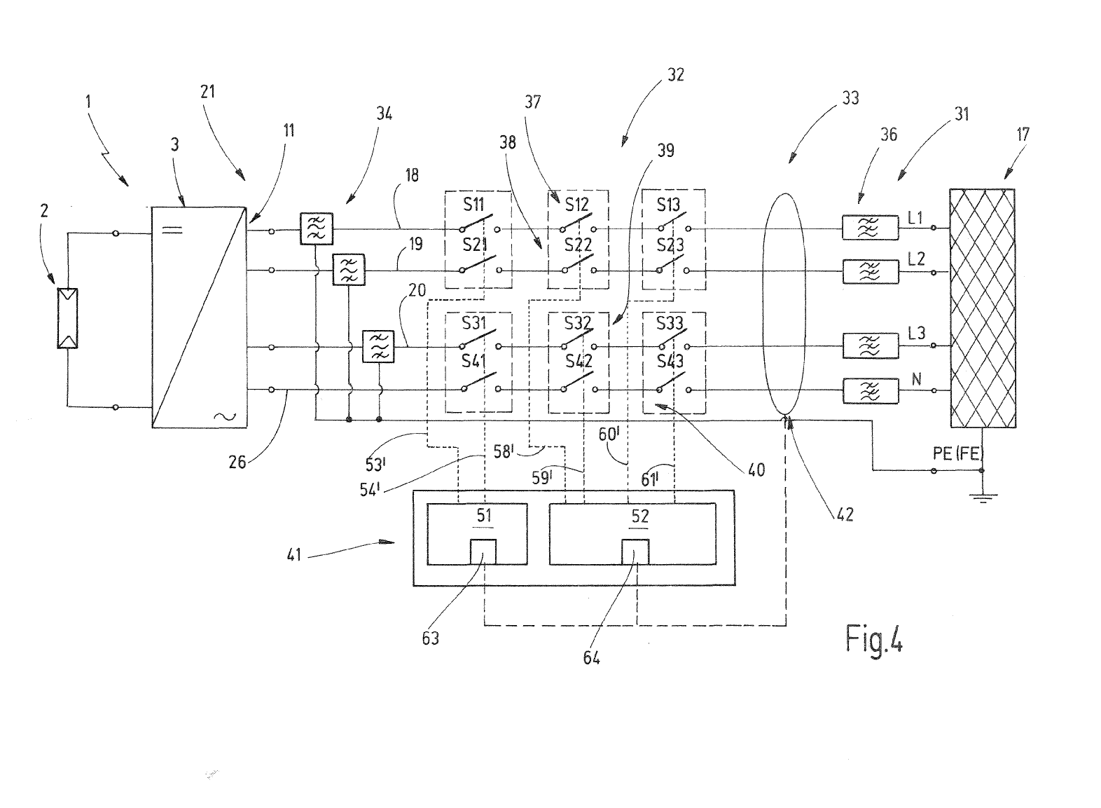

FIG. 4 a modified embodiment of the energy generating plant according to FIG. 1 or 2, in a largely simplified presentation; and

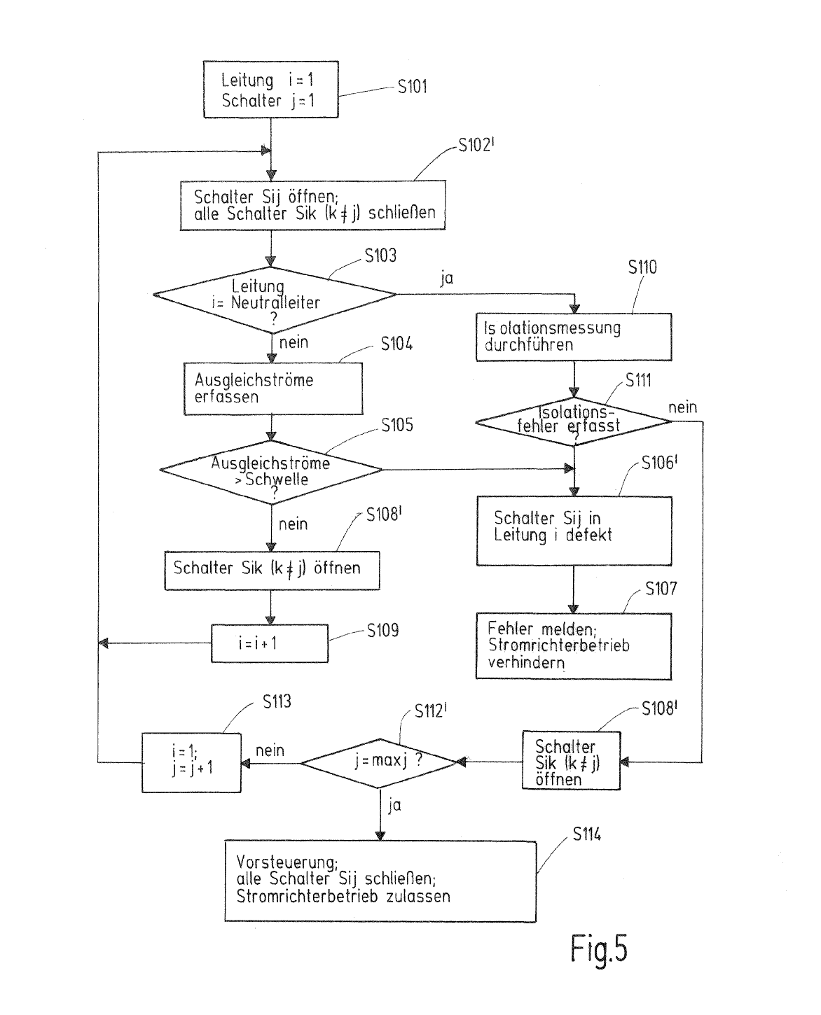

FIG. 5 a generalized flow chart for a function check of a separation device, respectively of the energy separation plant according to FIG. 4, in a simplified presentation.

In FIG. 1, in a largely schematic, partly block chart presentation, an energy generating plant 1 is depicted, provided for converting an electric direct current, which is supplied input-side from a generator 2, into an output-side alternating current. The energy generating plant 1 comprises the generator 2 and an in this case three-phase power converter 3, which could also be a one-phase power converter depending on demand. Herein a “power converter” is to be understood as any device that is able to convert electric energy of one type into electric energy of another type. This may be, for example, a rectifier for converting alternating current into direct current, a frequency converter for changing the frequency of an alternating current or an inverter for converting direct current into alternating current.

In a preferred embodiment the energy generating plant is a photovoltaic (PV) plant or a wind power plant or a plant based on fuel cells, which means that the generator 2 is implemented as a regenerative energy source, e.g. a PV generator comprising one or several PV modules (not depicted in detail), which are connected to each other to generate a DC voltage at the output of the PV generator and to supply a direct current. The power converter 3 is in this case implemented as an inverter, which converts a direct current supplied at its input into an alternating current (in this case three-phase alternating current) at its output.

Further regarding FIG. 1, the output poles of the generator 2, to which the input 7 of the power converter 3 is connected, are here designated by 4, 5. In particular, a positive input terminal 8 and a negative input terminal 9 of the power converter 3 is connected to the positive respectively negative pole 4, 5 of the generator 2. The power converter 3 further comprises an output 11 (having in this case five poles), to which belong the three output terminals (L1, L2, L3) 12, 13, 14 carrying the respective phases of the output-side AC voltage of the power converter 3, a neutral output terminal (N) 16 and a ground output terminal (PE respectively FE) 15 of the power converter 3.

The power converter 3, in particular inverter, may be of any preferably transformerless configuration that allows power conversion respectively inversion. Preferentially the power converter 3 comprises a power converter circuit (not shown in detail), which may, in a well-known fashion, comprise a parallel connection of, in this case for example, three substantially identical half-bridges or full-bridges each with switches that are respectively connected in series and are switched at high frequencies of up to 100 kHz according to given patterns, to the purpose of generating at the output 11 a suitable, in particular grid compatible AC voltage and a suitable alternating current from the input voltage and the input current. The alternating current supplied at the output 11 of the power converter 3 is used to be fed into a grid 17, the meaning of the term “grid” being herein extended to also comprise electric consumers, e.g. electric motor-generator drives, which are fed by the energy generating plant 1 and are also able to re-feed current into this. Otherwise the grid is preferably a power supply grid, respectively a public grid of a power provider. In the embodiment shown the three-phase alternating current fed into the grid 17 comprises three output currents which are equal in their absolute value and are phase-shifted with respect to each other by respectively 120 degrees.

The three output terminals 12-14 of the power converter 3 are connected, via respective phase conductors 18, 19, 20, to phase terminals 22, 23, 24, which implement the output terminals of the energy generation device—respectively the entire power converter/inverter arrangement between the generator 2 and the grid 17—collectively designated by “21” or implement the input terminals of the grid 17. Furthermore, the neutral output terminal 16 of the power converter 3 is connected via a neutral conductor (N conductor) 26 to a neutral terminal 27, which functions as an output terminal of the energy generating device 21 respectively as an input terminal of the grid 17. Moreover, at the ground output terminal 15 of the power converter 3 respectively at the corresponding output terminal 25 of the energy generating device 21, a protective ground conductor (PE conductor) designed as a protection from electric shock or a functional ground conductor (FE conductor) 28 for discharging equalizing currents or interference currents is provided, which is grounded (as indicated by the ground symbol 29) and to which preferably, grid-side, the neutral conductor 26 is also connected. A PE conductor 28 may extend over the entire plant, and preferably the housing of the generator 2 and the power converter 3 is also connected to said PE conductor 28.

As can further be seen in FIG. 1, further components of the output side of the power converter 3 are arranged in the phase conductors 18-20 and in the neutral conductor 26. Among these are, in particular, a noise filter device 31, a separation device 32 and a current sensor device 33.

The noise filter device 31 is provided for the suppression of high-frequency interferences at the output side of the power converter 3. In particular, the noise filter device 31 comprises in the embodiment shown at least one first and one second noise filter element 34, 36, which serve for filtering in particular asymmetrical interference voltages or currents, so-called common-mode interferences, which are, for example, caused by the high-frequency switching of the switching units of the power converter/inverter 3. In particular, in each phase conductor 18-20 respectively one first noise filter element 34 and one second noise filter element 36 are arranged.

The first noise filter element 34 is respectively inserted between the respective phase output terminal 12, 13, 14 of the power converter 3 and the separation device 32, and is in addition directly connected to the protective ground conductor (PE) 28 to discharge fault currents and interference currents against the ground 29 as the reference point. As an alternative, each first noise filter element 34 may be connected to a functional ground (FE) as is often provided for EMV (Electromagnetic Compatibility) filters in inverter arrangements. Regarding the functionality of the invention, the protective function of a protective ground conductor is not relevant. Crucial is, however, the possibility of discharging equalizing currents.

The second noise filter element 36 is inserted in each phase conductor 18, 19, 20 respectively between the separation device 32 and the grid-side phase terminal 22, 23, 24, and is usually implemented by a grid filter, e.g. an LC band pass filter or an LC low pass filter, according to general technical knowledge. The first noise filter element 34, the second noise filter element 36 and an optional ferrite core for the suppression of high-frequency interference portions, which are provided for improving electromagnetic compatibility, together implement the noise filter device 31.

The separation device 32 is provided for the potential separation of the power converter 3 from the grid 17 in case of a fault. To this purpose the separation device 32 comprises in each phase conductor 18, 19, 20 as well as in the neutral conductor 26 respectively one series circuit 37, 38, 39, 40 of a first controllable switch element Si1 and a second controllable switch element Si2 (i=1 to 4), which are in this preferred embodiment designed for the galvanic separation of the respective conductor. To put it more precisely, a first series circuit 37 of two controllable switch elements S11 and S12 is arranged in the L1 phase conductor 18, while a second series circuit 38 of two controllable switch elements S21, S22 is arranged in the L2 phase conductor 19, a third series circuit 39 of two controllable switch elements S31, S32 is arranged in the L3 phase conductor 20 and a fourth series circuit 40 of two controllable switch elements S41, S42 is arranged in the neutral conductor 26.

Preferably relays or contactors, which are suitable for switching in case of the huge electric power occurring in the present applications, are applied as controllable switch elements S11 . . . S42. For other applications, semiconductor switches, e.g. bipolar power transistors, MOSFET power transistors, IGBTs etc. may also be used, additionally or as an alternative.

In the normal feed-in operation of the power converter all (in this case eight) switch elements S11 . . . S42 are controlled for closing by a control device 41 (only depicted in a schematic fashion). In case of a fault or maintenance of the grid 17, all switch elements S11 . . . S42 can be controlled for closing by the control device 41, for the purpose of interrupting the connection between the power converter 3 and the grid 17 via the phase conductors 18-20 and the neutral conductor 26, thus effecting the potential separation required.

The current sensor device 33 is herein part of a so-called all-current sensitive fault current monitoring unit 42, which is sometimes also denominated an RCMU (Residual Current Monitoring Unit) and is, in particular, usually integrated in transformerless PV inverters for realizing an all-current sensitive fault circuit interrupter (AFI module). The all-current sensitive fault current monitoring unit 42 is provided for the protection of plants and persons and detects fault currents respectively leakage currents, embodied as direct currents, alternating currents and/or pulsed currents, which may occur, in particular, in an inverter, in the PV modules or in the wiring of the PV modules. If such a fault current or leakage current is captured, which exceeds a given limit value and can thus be dangerous for human beings, an automatic switch-off of the power converter 3 is effected via the separation device 32. For this no external fault current interrupter is required. The monitoring and evaluating logic of the all-current sensitive monitoring unit 42 can be part of a control logic of the control device 41 for controlling the power converter 3.

The current sensor device 33 itself is in the preferred embodiment implemented as a differential current sensor which all phase conductors 18-20 carrying the operating current from the power converter output 11 to the grid 17 and the neutral conductor 26 as primary conductors are looped through, in such a way that the differential current sensor 33 captures the difference respectively the sum of the alternating currents flowing through the primary conductors. Among these are, in particular, capacitive discharge currents which are, for example, systematically generated by a PV generator 2, possible ohmic fault currents which are, for example, caused by a damaged insulation of a PV plant, and discharge respectively equalizing currents which may be caused in the course of the checking procedure for the function check of the separation device 32, which is described below. All of these discharge currents respectively fault currents are reliably identifiable and distinguishable, following which a potential separation may be enforced by means of the separation device 32.

As for FIG. 2, further details of an embodiment of the energy generating plant 1 according to the invention are depicted. As can be seen, the first noise filter element 34 of the noise filter device 31 is here respectively embodied by a noise filter capacitor (C1) 43, 44, 45, which is respectively connected, on the one hand, at a point of a respective phase conductor 18, 19, 20 between the power converter output 11 and the separation device 32 and, on the other hand, to the protective ground conductor respectively functional ground conductor 28. The noise filter capacitors 43-45 discharge high-frequency interference signals, which are, for example, caused by operating electronic switches of the power converter 3, in this case against the protective ground respectively functional ground 29.

In FIG. 2 furthermore a possible implementation for the second noise filter element 36 of the noise filter device 31 is shown in a schematic fashion. The second noise filter element 36 comprises for the suppression of high interference frequencies suitable low-pass members, which are here embodied by LC members with inductivities (L) 47 respectively inserted in the phase conductors 18-20 and in the neutral conductor 26 and with capacitors (C2) 48, which are respectively connected to the inductivity outputs between the conductors 18-20 respectively 26 and the ground 29. As indicated by the coupled core, a current-compensated choke 49 is used here as inductivities 47, which choke 49 is able in a usual and conventional manner to effectively dampen so-called common-mode interferences occurring in the conductors in the same direction, with the same amplitude and phase.

The control device 41 is provided for controlling the switch elements S11 . . . S42 of the separation device 32. The control device 41 may be part of the control that controls the operation of the power converter 3. It can in particular be implemented together with said control in a software or firmware running on a shared processor. The control device 41 can, however, also be implemented separately from the control of the power converter. In any case the control device 41 is preferably implemented together with the logic of the all-current sensitive monitoring unit 42.

In a preferred embodiment as depicted in FIG. 2, the control device 41 comprises a first control unit 51 for controlling the first switch elements S11, S21, S31, S41 of all series circuits 37-40 in the conductors 18-20 and 26, and comprises a second separate control unit 52, which is provided for controlling the second switch elements S12, S22, S32, S42 in the conductors 18-20 and 26. The first and second control units 51, 52 are preferably implemented on different processors to create a desired redundancy allowing the desired one-fault tolerance. In this way it can be ensured, even in case of a defect of one of the control units 51, 52, that the other control unit can effect a potential separation in all conductors 18-20 and 26 by means of its allocated switch elements.

The first control unit 51 is operatively connected to the first switch elements S11, S21, S31, S41 via control lines 53-56, while the second control unit 52 is operatively connected to the second switch elements S12, S22, S32, S42 via respective second control lines 58-61. As can also be gathered from FIG. 2, each of the first and second control units 51, 52 comprises an evaluation unit 63, 64, which receives the signals provided by the current sensor device 33, compares them to given limit values and, for example in case the limit values are exceeded, outputs an error message and instructs the allocated control unit 51, 52 to control the corresponding switch elements S11 . . . S42 for opening. This may be effected both in operation in case of fault currents detected and in the checking procedure according to the invention for checking the separation device 32.

It has to be ensured that the potential separation device 32 functions reliably if required. In this regard the norm DIN EN 62109-2 stipulates that the insulation of the autonomous separation device is to be checked independently before an inverter starts operation. If a separation device is damaged resulting, for example, in some of the switch contacts being still closed even if the switch element is controlled for opening, this defect has to be reliably identified and then the inverter has to be prevented from starting respectively re-starting operation.

To ensure this, according the invention a checking procedure is provided, which is carried out by the control device 41 previous to the power converter 3 starting operation, to ensure a fault-free functionality of the separation device 32. In the following this checking process will be explained on the basis of FIG. 3.

It is assumed that the power converter 3, respectively a PV inverter, is supplied by the capacitor DC voltage. As soon as the capacitor 2, in particular PV capacitor 2, supplies a sufficient DC voltage, a sufficiently high input voltage is provided, which is above the peak grid voltage, allowing the power converter to generate a suitable voltage and to feed electric current into the grid 17. As part of a so-called feed-forward control routine, the power converter 3 then adapts its filters to the grid 17 for synchronizing with the grid 17 and connects to the grid 17 as soon as it is synchronous. Previous to the feed-forward control routine the power converter 3 carries out the checking routine shown in FIG. 3.

As shown in FIG. 3, firstly in step S101 the index i characterizing the conductor is set to 1. This means that the first phase conductor 18 (L1) is considered. Furthermore the index for the switch j is also set to 1.

Then in step S102 the switch Sij is controlled for closing. This means in the first run of the routine that the first switch S11 in the first phase conductor 18 is controlled for closing.

In the following step S103 the electric line i is checked whether it is the neutral conductor. If the electric line i is the neutral conductor, the procedure is continued with step S110, which will be described later on. If the electric line i is not the neutral conductor, as is the case, for example, for the phase conductors 18, 19 and 20, the next step is S104.

In step S104 possible equalizing currents are captured, which are caused by closing the switch Sij. If, for example in the present example, in which the switch S11 is closed, the second switch S12 of the series circuit 37 is defect and remains closed although it is controlled for opening, a current is initiated by closing the switch S11, which flows from the grid 17 over the first phase conductor 18, the grid filter 36 of the noise filter device 31 and the closed switches S11, S12 and is discharged to the protective ground conductor respectively functional ground conductor 28 via the noise filter capacitor (C1) 43. This discharge current is captured or registered by the differential current sensor 33 as an equalizing current or differential current fed from the grid 17 into the noise filter device 31. As the equalizing current flows into the noise filter device 31 via the phase conductor 18 and flows off to the ground 29 via the protective ground conductor/functional earth conductor 28, the sum respectively difference of all currents through the differential current sensor 33 is not equal to zero.

In the preferred embodiment with two separate control units 51, 52, if one of the first switches S11, S21, S31, S41 is controlled for closing, the signal characterizing the equalizing current is transmitted to the first evaluation unit 63 of the first control unit 51 for evaluation. If a second switch S12, S22, S32, S42 is controlled for closing, the equalizing current signal is transmitted to the second evaluation unit 64 of the second control unit 52 for evaluation. As an alternative, the equalizing current signal may be transmitted to both control units 51, 52 and the evaluation respectively monitoring can be carried out by both control units 51, 52 in parallel, thus creating increased redundancy and reliability.

In step S105 the respective evaluation unit 63, 64 checks whether there is a noticeable equalizing current. To this purpose, the evaluation unit 63, 64 can compare the signal characterizing the equalizing current, which it has received from the measuring device 33, for example, to a given threshold value. Other criteria regarding the expected form of the equalizing current signal may also be considered.

If the equalizing current signal leads to realizing that there is an equalizing current, e.g. as the intensity of the equalizing current exceeds a given threshold value, it is stated that the other switch Sik (k≠j) in the electric line i is defect (step S106). If, for example, one of the first switches S11, S21, S31 of a respective series circuit 37-39 is controlled for closing, then, if equalizing currents are detected, the respective second switch S12, S22, S32 must be regarded to be defect. In this case, as is shown in step S107, the fault is reported to a higher-up instance and may be indicated at the power converter 3, and a power converter operation is prevented.

In the other case, if no sufficient equalizing current is stated, in the next step S108 the switch Sij is opened and the index i for the electric line is increased by 1 (step S109) to check the following electric line. Then in the next iterative step the steps S102 to S109 and if applicable S110, S111 are repeated.

A jamming or agglutination of a contact in a switch S41, S42 in the neutral conductor 26 is not detectable in the way described above, as in the ideal case there is no voltage difference between the neutral conductor 26 and the protective ground conductor 28 and thus no equalizing process takes place. Usually there is also no noise filter capacitor C1 arranged, if viewed from the grid 17, downstream of the separation device 32, which could cause a corresponding equalizing current. For this case an insulation measurement is carried out at the power converter 3. Such insulation measurement routines are obligatory in controls for energy generating plants with inverters and are always present and are known in a variety of implementations. Usually, via a switch of an integrated measurement circuit, one of the input terminals 8, 9 of the power converter 3 is connected to the ground via a measurement resistor, as a result of which a current can flow off to the ground over the respective insulation resistor at the other power converter input terminal 9, 8 and over the measurement resistor. By the voltage drop at the measurement resistor the insulation resistance at the respective input terminal 9, 8 can be determined. The measurement can then be repeated for the other input terminal 8, 9 to determine the insulation resistance at this one.

In the routine for checking the functional reliability of the separation device 32, the insulation measurement is carried out in step S110 for the purpose of checking the functionality of the switches S41 and S42 in the neutral conductor 26. If herein, with the switch S41 (resp. S42) closed, it is detected in step S111 that there is an insulation fault, this indicates that there is a defect at the other switch S42 (resp. S41) in the neutral conductor 26 as the power converter 3 is now galvanically connected (depending on grid type) to the grid 17 and the insulation is hence no longer ensured. Therefore, in this case the switch S42 (resp. S41) is declared to be defect in step S106, as a result of which the fault is reported in step S107 and operation of the power converter 3 is prevented.

It is to be noted that besides the specific procedure for determining the insulation resistances there are numerous other insulation measuring procedures generally known in the technical field, which are as an alternative applicable in this case as well, to identify a defect of a contact of a switch S41, S42 in the neutral conductor 26.

If no insulation fault is captured in step S111, it is then checked in step S112 whether j=2, i.e. whether all switches S11 . . . S42 have already been subjected to the checking procedure. If this is not the case, the conductor index i is then set to i=1 in step S113 and the switch element index j is increased by 1, in this case set to 2, for the purpose of subsequently continuing the function check by way of the second switch elements S12, S22, S32, S42 in the conductors 18-20 and 26. The routine then returns to step S102, to iteratively carry out steps S102-S109 and, if applicable, S110, S111 for the second switch elements S12, S22, S32, S42, which are the next to be closed.

If all switches S11 . . . S42 have already been checked (yes in step S112), then in step S114 the feed-forward control routine is initiated. Within the feed-forward control routine, the power converter 3 is synchronized with the grid 17, following which all switch elements S11 . . . S42 of the separation device 32 are closed for connecting the power converter 3 to the grid 17 and starting its operation. The grid synchronization is effected after checking of the insulation of the power converter 3, wherein the insulation check may also be carried out before or during the function check of the separation device 32. All switches S11 . . . S42 remain closed as long as in the following feed-in operation no fault occurs that requires switching off the power converter 3.

The checking method according to the invention has numerous advantages. The checking device and the checking procedure can be rather easily implemented and allow, at low complexity, an efficient and reliable monitoring of the functional reliability of the potential separation of the energy generating plant. In particular the controllable switch elements S11 . . . S42 of the separation device 32 can be checked autonomously, quickly and reliably.

In already existing energy generating plants, e.g. in PV inverters, the checking method according to the invention can also be retrofitted with comparably low effort, preferably solely by an updatable additional software-based control logic of the control device 41. Usually a noise filter capacitor, e.g. C1 (43-45) in FIG. 2, is already provided in PV inverter circuits for noise suppression. If this is not the case, a noise filter capacitor can be added without difficulty. Moreover, a measuring device implemented as an all-current sensitive differential current sensor 33 (cf. FIGS. 1 and 2) is usually also already present in existing PV inverters. The same applies for an insulation measuring routine, which is absolutely obligatory for inverters. Thus no or only few additional structural elements are required.

A plurality of modifications is possible in the scope of the invention. As has already been mentioned, the energy generating device inserted between the generator 2 and the grid 17 in FIGS. 1 and 2 can be used for a variety of applications including generating of energy from photovoltaic, wind power or fuel cells for generating alternating current or direct current, for feeding electromotor drives, etc. In the case of an alternating current being generated, the energy generating device can be embodied in a one-phase, two-phase or three-phase implementation. The noise filter device may be embodied in different generally known configurations. In particular, the first noise filter element can comprise a discharge resistor connected in parallel, in addition to a noise filter capacitor (C1) 42-45, or may be realized by a different RLC circuit. It is crucial that a discharge or equalizing current flow is possible in the function check of the separation device. While separate measuring device could also capture said equalizing current instead of the differential current sensor 33, using the differential current sensor 33 is of advantage as then the all-current sensitive monitoring unit 42 can be used for different tasks. While principally the redundant implementation of the control device 41 with the two autonomous control units 51, 52 is not necessarily required, yet it is advantageous and adviseable regarding technical reliability.

In FIG. 4 further modifications of the invention are shown. Insofar as there is a congruency regarding construction and/or function, the above description together with FIGS. 1-3 is referred to, based on respectively identical reference numerals, for avoiding repetitions.

The embodiment shown in FIG. 4 differs from the implementation shown in FIGS. 1-3 first of all by the implementation of the separation device 32. Said separation device 32 comprises here contactors (or relays) as switch elements S11 . . . S42, each of which respectively comprising two switch contacts, which are controllable together and are arranged in different conductors 18-20 and 26. For example, a first contactor comprises the switch contacts S11, S12, which are arranged in the first phase conductor (L1) 18 and the second phase conductor (L2) 19 and are controlled together by the first control unit 51 via a first control line 53′. Furthermore a second contactor comprises two switch contacts S31, S41, which are arranged in the third phase conductor (L3) 20 and the neutral conductor 26 and are here controlled together by the first control unit 51 via a further first control line 54′. A third contactor comprises the switch contacts S12 and S22 in the first and second phase conductors 18, 20, which can be controlled together by the second control unit 52 via a second control line 60′. A fourth contactor or relay comprises the switch contacts S32 and S42, which are arranged in the third phase conductor 20 and the neutral conductor 26 and can be controlled together by the second control unit 52 via the shared further second control line 59′.

By this configuration the number of structural elements, in particular of contactors or relays, and of the control lines for these can be reduced as well as the space required for these. The control logic of the control unit 41 and the logic for the functional reliability check of the separation device 32 are simplified.

In a similar way as has been described in the context of FIG. 3, for the function check of the separation device 32 first of all the contactor (or relay) with the switch elements respectively switch contacts S11 and S21 can be controlled for closing. If equalizing currents occur, it is to be assumed (not considering the additional switch elements S13, S23, S33, S43 described below) that the contactor with the contacts S12 and S22 is defect.

If the contactor with the switch elements S31 and S41 is controlled for closing by the first control unit 51 and equalizing currents occur, the contactor with the switch elements S32 and S42 is defect.

An agglutination or jamming of the switch element S42 in the neutral conductor 26 is checked by insulation measuring. If an insulation fault is detected, the switch element S42 is defect.

The process is then repeated with the further contactors by controlling all contactors for opening and then controlling the contactor with the contacts S12 and S22 for closing. If there are equalizing currents, the contactor with the contacts S11 and S21 is defect.

Following this, the contactor with the switch elements S32 and S42 is controlled for closing and the contactor with the contacts S31 and S41 is regarded as defect if in this case equalizing currents are flowing.

An agglutination or jamming of the contact S41 in the neutral conductor 26 is checked by insulation measuring and this is regarded as defect if an insulation fault is detected.

FIG. 4 shows a further modification, which may be carried out by the separation device 32 according to the invention, additionally or as an alternative. As can be seen in FIG. 4, the separation device 32 is here depicted respectively comprising an additional third switch element in each conductor 18-20 and 26 between the output 11 of the power converter 3 and the grid-side terminals 22-24 and 27. A switch element S13 is connected in series to the switch elements S11 and S12, a further third switch element 23 is arranged in series to the switch elements S21 and S22, a further third switch element S33 is arranged in series to the switch elements S31 and S32, and a further third switch element S43 is arranged in series to the switch elements S41 and S42. By providing the additional, third switch elements S13, S23, S33 and S43 in the separation device 32, an additional security is achieved as regards a sufficient galvanic separation. The three switch elements per series circuit 37-40 result in a greater airbreak distance, which may also be sufficient if one of the switch elements is defect, i.e. is agglutinated or jammed, or if the other switch elements are already somewhat damaged due to aging, corrosion and contamination. Maintenance or replacement activities may be reduced to a minimum.

In FIG. 4 the third switch elements S13, S23, S33 and S43 are shown in the way they are controllable by the second control unit 52 via control lines 60′, 61′. As an alternative, they could also be actuable by the first control unit 51 or by a separate, additional control unit (not shown in detail) of the control device 41.

Furthermore, the pairs of switch elements S13, S23 respectively S33, S43 may embody switch contacts of one single contactor, which are respectively controllable together, as has been described above in the context of the switch contacts S11 . . . S42 in the implementation according to FIG. 4. There could also further switch elements be provided in each series circuit 37-40, to further increase reliability, or contactors respectively relays could be used with more than two switch contacts that are controllable together.

Generally the function check in case of at least three switch elements per phase conductor 18-20 and neutral conductor 26 corresponds to the method described above in context with FIG. 3. FIG. 5 shows a flow chart concerning the general case that maxj switches (maxj=3 as shown in FIG. 4 or greater) are used in each series circuit 37-40 of the separation device 32. The flow chart according to FIG. 5 largely corresponds to the one according to FIG. 3, because of which principally, to avoid repetition, the corresponding explanations may be referred to and only the differences will be described in the following.

In the modified step S102′ the switch Sij, namely the switch j in the conductor i, is now controlled for opening, while all other switches Sik (k≠j) are controlled for closing. If equalizing currents are captured in step S105, then it must be stated in the modified step

S106′ that the switch Sij is defect. Furthermore, step S108′ is to be modified insofar as now all switches Sik (k≠j) are controlled for opening to check the following switch Sij. In step 112′ it is checked whether all switch elements j (j=1 to maxj) in all conductors 18-20 and 26 have been checked.

It is obvious that in the checking method according to FIG. 3 or FIG. 5 the sequence of the steps, in particular the checking sequence of the conductors i and/or of the switch elements j, can be changed without leaving the scope of the invention.

An energy generating device for generating electric energy, in particular from regenerative energy, for feeding into a grid 17 comprises a power converter 3, at least one electric line for electrically connecting the power converter 3 to the grid 17, a separation device 32 for the potential separation of the power converter from the grid, wherein the separation device 32 includes a series circuit 37-40 that is arranged in the at least one electric line 18-20, 26 and consists of at least two separately controllable switch elements S11 . . . S43, a noise filter device 31 including at least one noise filter element 34, which is connected to the electric line 18-20 between the output 11 of the power converter 3 and the separation device 32, for discharging high-frequency interference signals against a reference point, a measuring device 33 for capturing discharge currents flowing over the noise filter element 34 and for delivering discharge current signals to characterize said discharge currents, and comprises a control device 41 for controlling the switch elements S11 . . . S43 of the separation device 32. To the purpose of checking the switch elements for functional reliability, the control device 41 is provided to optionally control at least one of the switch elements S11 . . . S43 of a series circuit 37-40 for closing, to receive a discharge current signal from the measuring device 33 and to identify a defect of at least one other of the switch elements in the series circuit by the discharge current signal. Furthermore, a method has been created to check the functional reliability of a potential separation device of an energy generating device.

1. An energy generating device for generating electric energy from an energy source, in particular a regenerative energy source, and for feeding the generated electric energy into a grid, in particular a power supply grid, comprising:
a power converter for converting energy at its input into a grid compatible energy at its output;
at least one electric line (for electrically connecting the output of the power converter to the grid;
a separation device for a potential separation of the power converter from the grid, wherein the separation device comprises a series circuit that is arranged in the at least one electric line and consists of at least two separately controllable switch elements;
a noise filter device that includes at least one noise filter element connected to the at least one electric line between the output of the power converter and the separation device and provided for discharging high-frequency interference signals against a reference point;
a measuring device for capturing discharge currents flowing over the noise filter element and for delivering a discharge current signal characterizing a respective discharge current; and
a control device for controlling the switch elements of the separation device, wherein the control device is designed for the function check of the separation device to optionally control at least one of the switch elements of the at least one series circuit for closing, to receive a discharge current signal from the measuring device and to identify by the discharge current signal a defect of at least one other of the switch elements of the at least one series circuit.

2. The energy generating device according to claim 1, wherein the energy generating device is a photovoltaic device for generating electric energy from an energy supplied by a photovoltaic generator by means of a preferably transformerless photovoltaic inverter.

3. The energy generating device according to claim 1, wherein
the power converter is implemented by a one-phase or multi-phase inverter, which inverts input-side DC voltage energy into output-side AC voltage energy and the output of which comprises at least one first phase terminal and a neutral terminal;
the at least one electric line comprises at least one first phase conductor connected to the first phase terminal and a neutral conductor connected to the neutral terminal; and
the separation device comprises at least one first series circuit of at least one first and second switch element which are arranged in the first phase conductor, and comprises a further series circuit of at least one further first and second switch element which are arranged in the neutral conductor.

4. The energy generating device according to claim 3, comprising:
a three-phase inverter with three phase terminals and one neutral terminal at its output, with three phase conductors and one neutral conductor each running between a respective one of the phase terminals or the neutral terminal of the inverter output and an allocated grid-side terminal; and
in each phase conductor and in the neutral conductor, one respective series circuit of at least one first and second switch element of the separation device.

5. The energy generating device according to claim 1, wherein the separation device comprises more than two separately controllable switch elements in each series circuit of the at least one electric line, and
the control device is designed to optionally control simultaneously all except one single of the switch elements of the series circuit for closing, to receive a discharge current signal from the measuring device and to identify a defect of the one single switch element of the series circuit on the basis of the discharge current signal.

6. The energy generating device according to claim 1, wherein the switch elements of the separation device are implemented by contactors or relays, each contactor or relay preferably having two or several collectively controllable switch contacts of the same type, which are arranged in different conductors of the at least one electric line.

7. The energy generating device according to claim 1, wherein the at least one noise filter element is a noise filter capacitor, which is preferably connected between a phase conductor of the at least one electric line and a protective ground or functional ground.

8. The energy generating device according to claim 1, wherein the measuring device is part of an all-current sensitive fault current monitoring unit.

9. The energy generating device according to claim 1, wherein the measuring device comprises a measurement current converter implemented as a differential current sensor, through which are looped all conductors running between the power converter side output terminals and the grid-side terminals and which is provided for capturing the current difference.

10. The energy generating device according to claim 1, wherein the control device and the measuring device are provided to carry out the function check of the separation device before the power converter, in particular inverter, starts operation.

11. The energy generating device according to claim 1, wherein the control device comprises a comparator device for comparing the discharge current signal received from the measuring device to a threshold value and for identifying a defect of the separation device if the threshold value is exceeded.

12. The energy generating device according to claim 1, wherein the control device is provided to simultaneously control at least two first switch elements respectively second switch elements, in different phase conductors or in one phase conductor and one neutral conductor of the at least one electric line, for opening or closing.

13. The energy generating device according to claim 1, wherein the control device comprises a first control unit for controlling the first switch elements of all series circuits, the at least one second control unit to control the second switch elements of all series circuits of the at least one electric line.

14. The energy generating device according to claim 1, wherein furthermore an insulation measuring device is provided for determining an insulation resistance of the power converter, the control device being designed to detect, on the basis of an insulation resistance determined by the insulation measuring device, a defect of one of the switch elements in a neutral conductor of the at least one electric line while controlling the at least one other of the switch elements for closing.

15. A method for checking the functional reliability of a potential separation device of an energy generating device for generating electric energy from an energy source, in particular a regenerative energy source, and for feeding the generated electric energy into a grid, in particular a power supply grid, wherein
the energy generating device comprises:
a power converter for converting energy at its input into a grid compatible energy at its output;
at least one electric line for electrically connecting the output of the power converter to the grid; and,
the separation device for potential separation of the power converter from the grid,
the separation device comprising a series circuit that is arranged in the at least one electric line and consisting of at least two controllable switch elements and comprising a noise filter device including at least one noise filter element, which is connected to the at least one electric line between the output of the power converter and the separation device, for discharging high-frequency interference signals against a reference point,
wherein the method has the following steps:
controlling at least one of the switch elements of the at least one series circuit for closing,
measuring an equalizing current initiated as a reaction to the closing of the at least one switch element by the noise filter element; and
detecting by the measured discharge current, a defect of another one of the switch elements of the at least one series circuit.

16. (canceled)

17. The energy generating device according to claim 1, wherein the measuring device comprises a measurement current converter implemented as a differential current sensor, which all phase conductors carrying the operating current from the power converter output to the grid and the neutral conductor as primary conductors are looped through, in such a way that the differential current sensor captures the difference respectively the sum of the alternating currents flowing through the primary conductors and which is provided for capturing the current difference.

18. The energy generating device according to claim 1, wherein furthermore an insulation measuring device is provided for determining an insulation resistance at at least one of the input terminals of the power converter with respect to ground, the control device being designed to detect, on the basis of an insulation resistance determined by the insulation measuring device, a defect of one of the switch elements in a neutral conductor of the at least one electric line while controlling the at least one other of the switch elements for closing.
